(19) United States
(12) Patent Application Publication
(10) Pub. No.: US 2023/0387218 A1
(43) Pub. Date: Nov. 30, 2023

(54) SEMICONDUCTOR DEVICE AND METHOD OF MANUFACTURING THE SAME

(71) Applicant: Mitsubishi Electric Corporation, Tokyo (JP)

(72) Inventors: Taiki HOSHI, Tokyo (JP); Kenji SUZUKI, Tokyo (JP); Yuki HARAGUCHI, Tokyo (JP); Haruhiko MINAMITAKE, Tokyo (JP); Hidenori KOKETSU, Tokyo (JP); Yusuke MIYATA, Tokyo (JP); Akira KIYOI, Tokyo (JP)

(73) Assignee: Mitsubishi Electric Corporation, Tokyo (JP)

(21) Appl. No.: 18/163,233

(22) Filed: Feb. 1, 2023

(30) Foreign Application Priority Data
May 24, 2022 (JP) 2022084633

(51) Int. Cl. H01L 29/36; H01L 21/22

(52) U.S. Cl. CPC H01L 29/36; H01L 21/2225

(57) ABSTRACT

A semiconductor device includes a drift region that is of first conductive type and formed in a semiconductor substrate; a hydrogen buffer region that is of first conductive type, positioned on the back surface side of the drift region, contains hydrogen as impurities, and has impurity concentration higher than impurity concentration of the drift region; a flat region that is of first conductive type, positioned on the back surface side of the hydrogen buffer region, and has impurity concentration higher than impurity concentration of the drift region; and a carrier injection layer that is of first or second conductive type, positioned on the back surface side of the flat region, and has impurity concentration higher than impurity concentrations of the hydrogen buffer region and the flat region. The hydrogen buffer region and the flat region each have a constant oxygen concentration of 1E16 atoms/cm³ to 6E17 atoms/cm³ inclusive.

### FIELD

The present disclosure relates to a semiconductor device including a power semiconductor element such as an IGBT or a diode and a method of manufacturing the same.

### BACKGROUND

A semiconductor device disclosed in Patent Literature 1 described below includes a semiconductor substrate, an anode layer formed on a front surface side of the semiconductor substrate, a cathode layer formed on a back surface side of the substrate, and an n-type buffer region formed between the anode layer and the cathode layer. In the semiconductor device, oxygen concentration from the anode layer to the buffer region is defined.

### CITATION LIST

### Patent Literature

Patent Literature 1: JP 2014-99643 A

### SUMMARY

### Technical Problem

In Patent Literature 1 described above, oxygen concentration from the buffer region to the cathode layer is not defined, and the oxygen concentration from the buffer region to the cathode layer monotonically decreases. In this case, it has been found that when a proton buffer region is formed in one step into a semiconductor substrate having an oxygen concentration of 1E16 atoms/cm³ to 6E17 atoms/cm³ inclusive to increase throughput, buffer effect decreases, for example, formation anomaly of a carrier concentration profile, increase of leakage current, and incapability of preventing oscillation at turn-off occur.

The present disclosure is intended to solve the above-described problem and provide a semiconductor device that does not suffer formation anomaly of a carrier concentration profile and can reduce leakage current when one hydrogen buffer region is formed in one step into a semiconductor substrate having an oxygen concentration of 1E16 atoms/cm³ to 6E17 atoms/cm³ inclusive, and a method of manufacturing the same.

### Solution to Problem

A semiconductor device according to the present disclosure comprises a drift region that is of first conductive type and formed in a semiconductor substrate; a hydrogen buffer region that is of first conductive type, positioned on the back surface side of the drift region, contains hydrogen as impurities, and has impurity concentration higher than impurity concentration of the drift region; a flat region that is of first conductive type, positioned on the back surface side of the hydrogen buffer region, and has impurity concentration higher than impurity concentration of the drift region; and a carrier injection layer that is of first or second conductive type, positioned on the back surface side of the flat region, and has impurity concentration higher than impurity concentrations of the hydrogen buffer region and the flat region. The hydrogen buffer region and the flat region each have a constant oxygen concentration of 1E16 atoms/cm³ to 6E17 atoms/cm³ inclusive.

A method of manufacturing the semiconductor device described above, according to the present disclosure, comprises: a step of preparing the semiconductor substrate having an oxygen concentration of 1E16 atoms/cm³ to 6E17 atoms/cm³ inclusive; an injection step of injecting protons within a depth of 10 μm from the back surface of the semiconductor substrate in a dose amount of 4E13 atoms/cm³ or smaller; and an activation step of activating the protons injected in the injection step through thermal treatment at 400° C. A relational expression of Z<0.03T+5 is satisfied in a range of 30<T<240 where Z μm is the depth and Tmin is a thermal treatment time in the activation step.

A method of manufacturing the semiconductor device described above, according to the present disclosure, comprises: a step of preparing the semiconductor substrate having an oxygen concentration of 1E16 atoms/cm³ to 6E17 atoms/cm³ inclusive; an injection step of injecting protons within a depth of 15 μm from the back surface of the semiconductor substrate in a dose amount of 4E13 atoms/cm³ or smaller; and an activation step of activating the protons injected in the injection step through thermal treatment at 430° C. for 120 minutes.

### Advantageous Effects of Invention

According to the present disclosure, when one hydrogen buffer region is formed in a semiconductor substrate having an oxygen concentration of 1E16 atoms/cm³ to 6E17 atoms/cm³ inclusive, generation of a high-resistance layer in a flat region is prevented and formation anomaly of a carrier concentration profile does not occur. With the flat region including no high-resistance layer and with a hydrogen buffer region, dynamic abrupt change of a depleted layer is reduced and thus surge voltage can be decreased, thereby preventing oscillation.

### BRIEF DESCRIPTION OF THE DRAWINGS

FIGS. 1A and 1B are cross-sectional views to explain a method of manufacturing a semiconductor device according to a first embodiment.

FIGS. 2A and 2B are cross-sectional views to explain a method of manufacturing a semiconductor device according to the first embodiment.

FIGS. 3A and 3B are cross-sectional views to explain a method of manufacturing a semiconductor device according to the first embodiment.

FIGS. 4A and 4B are cross-sectional views to explain a method of manufacturing a semiconductor device according to the first embodiment.

FIGS. 5A and 5B are cross-sectionals view to explain a method of manufacturing a semiconductor device according to the first embodiment.

FIG. 6 is a cross-sectional view to explain a method of manufacturing a semiconductor device according to the first embodiment.

FIG. 7 is a diagram showing an oxygen concentration profile in a semiconductor substrate of the semiconductor device according to the first embodiment without a high-resistance layer.

FIG. 8 is a schematic diagram showing the oxygen concentration profile shown in FIG. 7 and the oxygen concentration profile in the semiconductor substrate having a high-resistance layer.

FIG. 9 is a schematic diagram showing the relationship between an activation time of hydrogen and the distance of a hydrogen buffer region from a back surface electrode.

FIG. 10 is a schematic diagram showing a boundary line between the occurrence and non-occurrence of the high-resistance layer in terms of the relationship between the oxygen concentration in the semiconductor substrate and the distance of the hydrogen buffer layer from the back surface electrode.

FIGS. 11A and 11B are schematic diagrams showing the relationship between a carbon concentration in the semiconductor substrate and a difference between a carrier concentration of the flat region and the carrier concentration of the drift region.

FIG. 12 is a graph showing the relationship between the oxygen concentration in the semiconductor substrate and the distance of the hydrogen buffer region from the back surface electrode when an activation temperature is changed.

FIG. 13 is a photoluminescence (PL) spectrum diagram showing a carrier profile when no high-resistance layer is formed in the flat region.

### DESCRIPTION OF EMBODIMENTS

An embodiment will be described below with reference to the accompanying drawings. Common or corresponding elements in the drawings are denoted by the same reference sign, and description thereof is simplified or omitted.

### First Embodiment

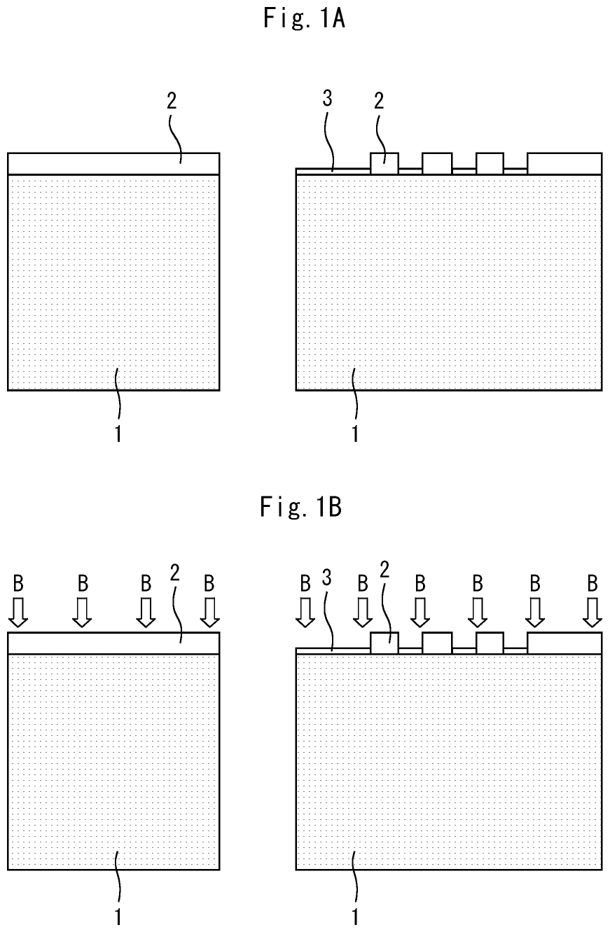

A method of manufacturing a semiconductor device according to a first embodiment will be described below with an example in which an IGBT is manufactured with reference to FIGS. 1A to 6. In each drawing, the left-side part illustrates a cell part, and the right-side part illustrates a terminal end part including a gate wire. In the present embodiment, a case in which a first conductive type is the n type and a second conductive type is the p type will be described below as an example, but the first conductive type may be the p type and the second conductive type may be the n type. Note that conditions known to the skilled person in the art can be used as specific process conditions below unless otherwise described in detail.

First, as illustrated in FIG. 1A, an n-type silicon substrate as a semiconductor substrate 1 is prepared. The semiconductor substrate 1 is manufactured by slicing a large-diameter silicon single crystal manufactured by an MCZ method. Hereinafter, the upper surface of the semiconductor substrate 1 illustrated in FIGS. 1A and 1B is referred to as a front surface, and the lower surface thereof is referred to as a back surface. The semiconductor substrate 1 includes a drift region Rd to be described later between the front surface and the back surface. The oxygen concentration and carbon concentration of the semiconductor substrate 1 are measured at manufacturing and known. The oxygen concentration of the semiconductor substrate 1 is preferably, for example, 1E16 atoms/cm³ to 6E17 atoms/cm³ inclusive. The p-type impurity concentration of the semiconductor substrate 1 is determined in accordance with the withstand voltage of the semiconductor device.

Subsequently, a silicon oxide film 2 for forming a p-type well layer 4 to be described later is formed on a surface layer of the semiconductor substrate 1 at the terminal end part by, for example, a plasma CVD method. The film thickness of the silicon oxide film 2 is set to such a thickness that the silicon oxide film 2 can function as a hard mask. Subsequently, an unillustrated resist pattern is formed by using a photoengraving technology, and the silicon oxide film 2 at the terminal end part is selectively etched with the resist pattern as a mask. Thereafter, a hard mask made of the silicon oxide film 2 as illustrated in FIG. 1A is obtained by removing the resist pattern. The hard mask covers the entire front surface of the semiconductor substrate 1 at the cell part and selectively covers the front surface of the semiconductor substrate 1 at the terminal end part. A mat oxide film 3 is formed by a thermal oxidation method on the front surface of the semiconductor substrate 1 that is not covered by the hard mask, and accordingly, a structure illustrated in FIG. 1A is obtained. The film thickness of the mat oxide film 3 is set so that damage on the front surface of the semiconductor substrate 1 can be reduced, and is set to be smaller than that of the silicon oxide film 2.

Subsequently, as illustrated in FIG. 1B, boron (B) as p-type impurities is selectively injected into the semiconductor substrate 1 at the terminal end part by using an ion injection technique with the silicon oxide film 2 as the hard mask. Note that boron may be selectively injected with the resist pattern as a mask in place of the hard mask.

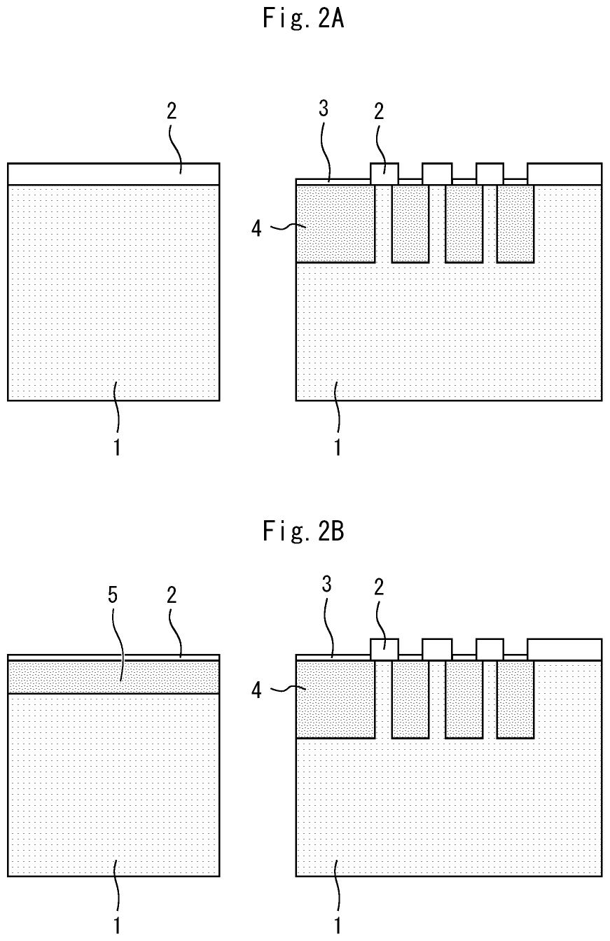

Subsequently, the injected boron is activated through thermal treatment in a nitrogen atmosphere at a high temperature of 1000° C. or higher for 240 minutes or longer. Accordingly, as illustrated in FIG. 2A, the p-type well layer 4 is formed on the front surface side of the semiconductor substrate 1 at the terminal end part.

Subsequently, the silicon oxide film 2 formed at the cell part is thinned and then, as in the case of the p-type well layer 4, boron as p-type impurities is injected into the front surface of the semiconductor substrate 1 at the cell part by using the ion injection technique. Thereafter, the boron is activated through thermal treatment. Accordingly, as illustrated in FIG. 2B, a p-type base layer 5 is formed on the front surface side of the semiconductor substrate 1 at the cell part.

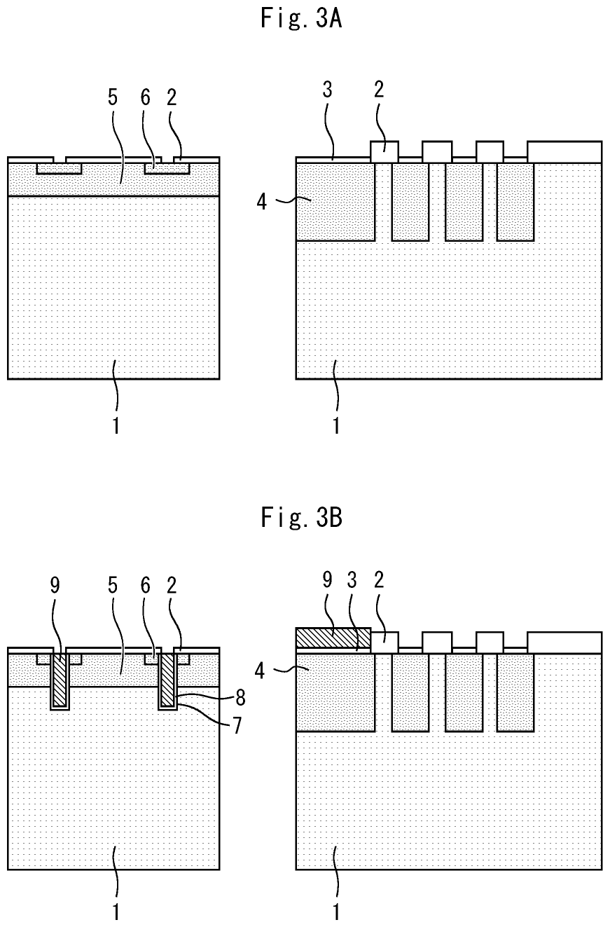

Subsequently, the silicon oxide film 2 formed at the cell part is patterned by using the photoengraving technology and etching. N-type impurities such as phosphorus or arsenic are injected with the patterned silicon oxide film 2 as a mask. Thereafter, the n-type impurities are activated through thermal treatment, and accordingly, a n⁺-type emitter layer 6 is formed at the cell part as illustrated in FIG. 3A.

Subsequently, the semiconductor substrate 1 is etched with the silicon oxide film 2 as a mask, and accordingly, a trench 7 penetrating through the n⁺-type emitter layer 6 and reaching the drift region Rd is formed as illustrated in FIG. 3B. Subsequently, a silicon oxide film as a gate insulating film 8 is formed on the inner surface of the trench 7 by using the thermal oxidation method. Thereafter, a polysilicon 9 as an electrode material is embedded in the trench 7 in which the gate insulating film 8 is formed. The polysilicon 9 may be formed by a CVD method or a sputtering method. Accordingly, a trench gate made of the polysilicon 9 and extending to the drift region Rd is formed. The polysilicon 9 is used not only as the trench gate at the cell part but also as the gate wire at the terminal end part. Note that, in the present embodiment, the n⁺-type emitter layer 6 is formed before the trench gate is formed, but the n⁺-type emitter layer 6 may be formed after the trench gate is formed.

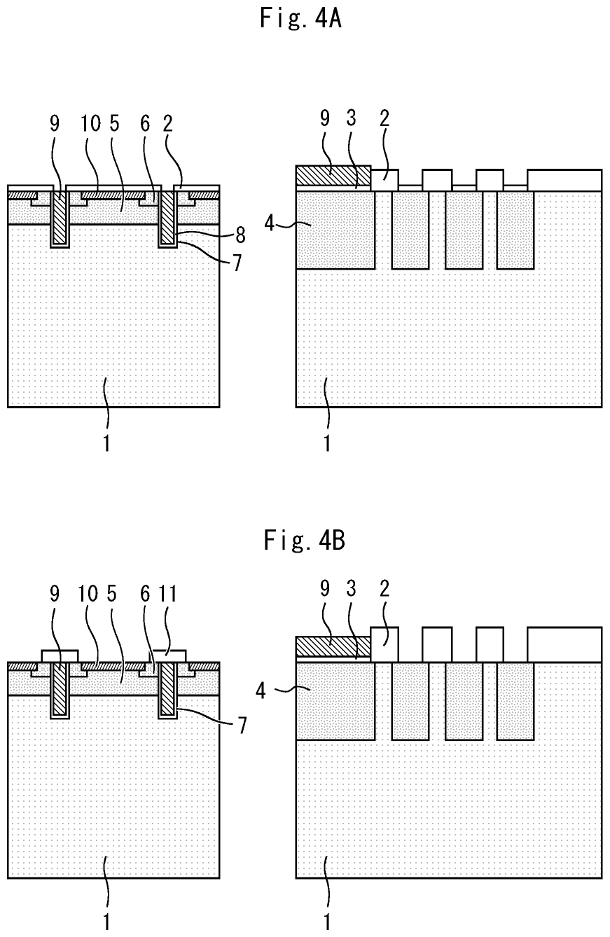

Subsequently, the silicon oxide film 2 formed at the cell part is removed. Thereafter, as illustrated in FIG. 4A, p-type impurities such as boron are selectively injected into the front surface at the cell part, and the injected p-type impurities are activated through thermal treatment. Accordingly, a p⁺ layer 10 is formed. Note that the n-type impurities for the n⁺-type emitter layer 6 and the p-type impurities for the p⁺ layer 10 may be simultaneously activated through single thermal treatment.

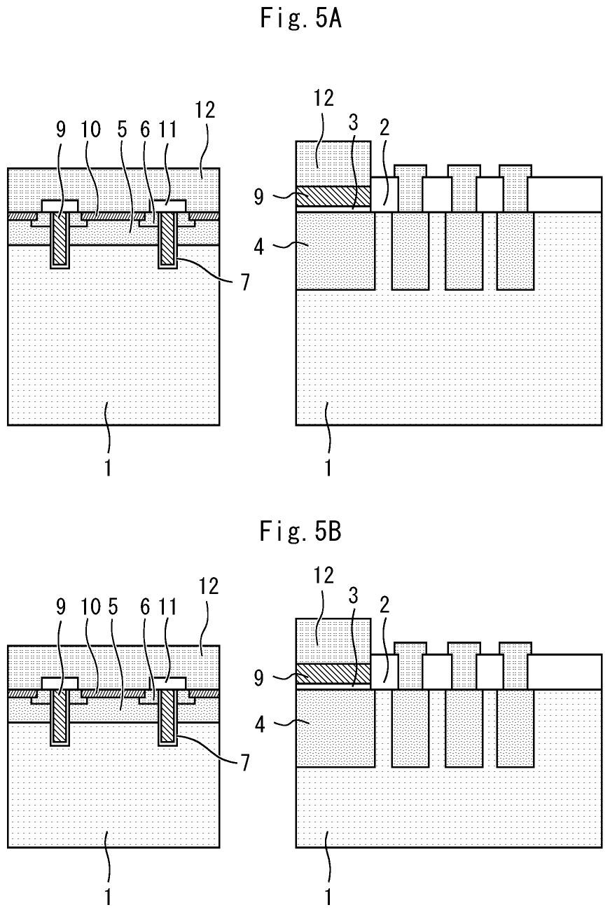

Subsequently, as illustrated in FIG. 4B, an oxide film pattern 11 is formed and a contact region that a front surface electrode 12 to be described later contacts is formed. Thereafter, as illustrated in FIG. 5A, the front surface electrode 12 is formed. Although not illustrated, a front surface protective film such as silicon nitride or polyimide may be formed as necessary.

Following the above-described treatment on the front surface side of the semiconductor substrate 1, treatment on the back surface side of the semiconductor substrate 1 is performed. First, as illustrated in FIG. 5B, the semiconductor substrate 1 is ground from the back surface side to a thickness in accordance with device withstand voltage.

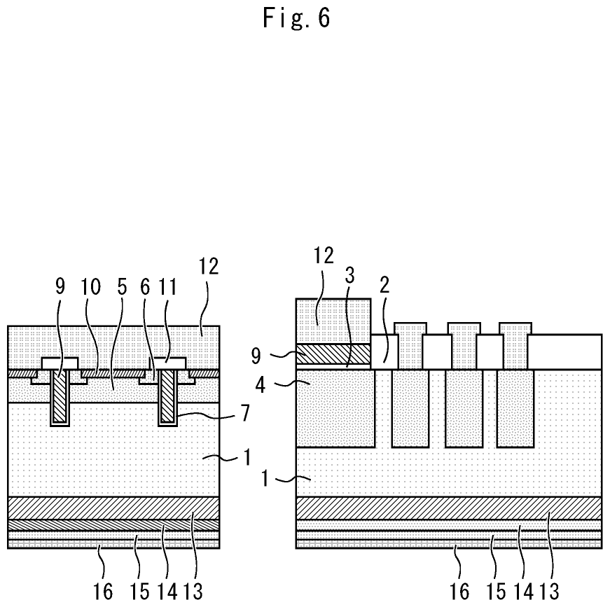

Subsequently, hydrogen (H⁺) for forming a hydrogen buffer layer 13 to be described later is injected from the back surface side of the semiconductor substrate 1. Then, n-type impurities such as phosphorus for forming a phosphorus buffer layer 14 to be described later are injected on the back surface side of the hydrogen. Arsenic may be injected in place of phosphorus. In addition, p-type impurities such as boron for forming a collector layer 15 to be described later are injected on the back surface side of the phosphorus. Thereafter, annealing is performed to activate the phosphorus and the boron, and accordingly, the phosphorus buffer layer 14 and the collector layer 15 are formed. The phosphorus buffer layer 14 and the collector layer 15 are collectively formed through a single annealing process but may be formed through respective annealing processes. The phosphorus buffer layer 14 and the collector layer 15 correspond to the carrier injection layer. In addition, annealing is performed to activate the hydrogen, and accordingly, the hydrogen buffer layer 13 is formed. Thereafter, a back surface electrode 16 is formed, and accordingly, the semiconductor device having a structure illustrated in FIG. 6 is obtained.

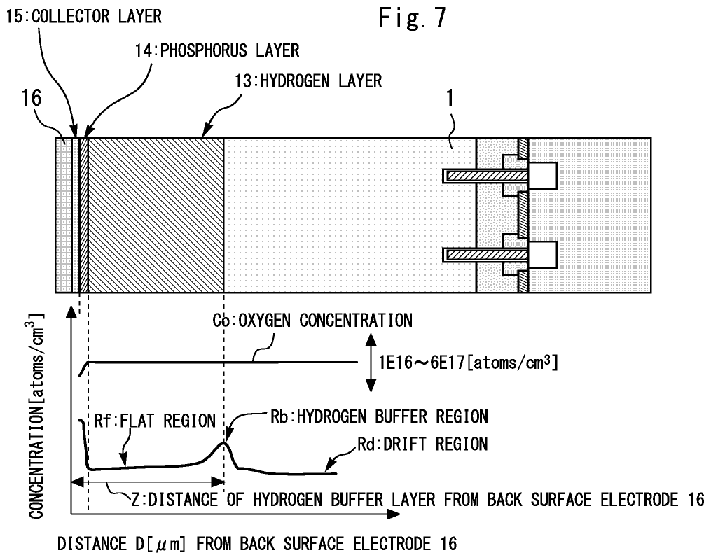

In the semiconductor device of first embodiment, as illustrated in FIG. 7, an oxygen concentration Co in the semiconductor substrate 1 is, for example, 1E16 atoms/cm³ to 6E17 atoms/cm³ inclusive, and the oxygen concentration Co is constant in a flat region Rf, a hydrogen buffer region Rb, and the drift region Rd.

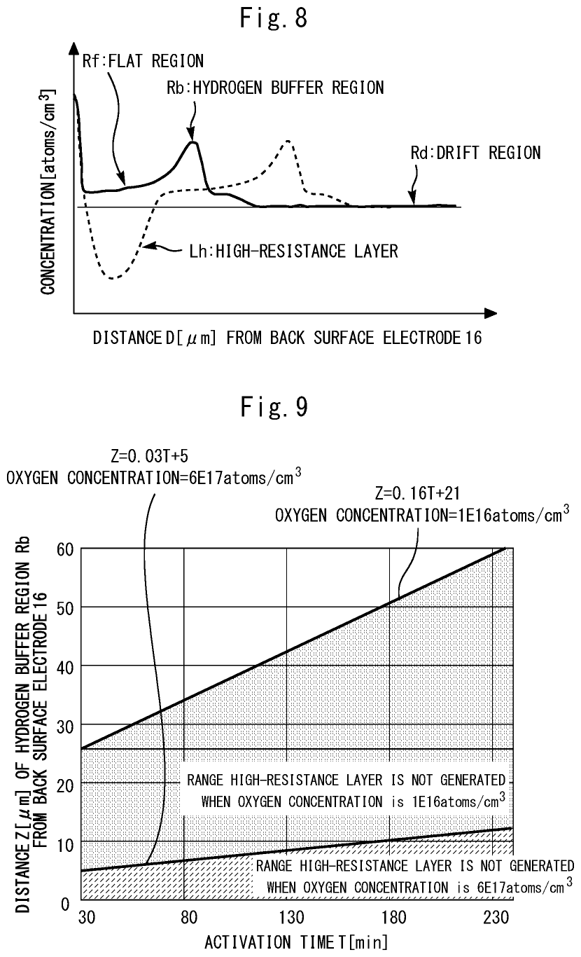

A process of forming the hydrogen buffer layer 13 will be described below. Typically, hydrogen injected into the semiconductor substrate 1 tends to be unlikely to diffuse inside the semiconductor substrate 1 as the oxygen concentration in the semiconductor substrate 1 increases. Thus, as illustrated in FIG. 8, the oxygen concentration Co in the semiconductor substrate 1 and injection and activation conditions of hydrogen need to be considered for a distance Z of the hydrogen buffer layer 13 from the back surface electrode 16. For example, when the oxygen concentration in the semiconductor substrate 1 is 6E17 atoms/cm³, the distance Z of the hydrogen buffer layer 13 from the back surface electrode 16 is preferably 10 μm or shorter for performing hydrogen injection in a dose amount with which the hydrogen buffer layer 13 has a peak concentration of 1E15 atoms/cm³ or lower and hydrogen activation for 160 minutes in a nitrogen or hydrogen atmosphere at 400° C. The dose amount may be set to, for example, 4E13 atoms/cm³ or lower. When the injection condition of hydrogen is changed so that the distance Z of the hydrogen buffer layer 13 from the back surface electrode 16 is 10 μm or larger without changing the activation condition thereof, a high-resistance layer Lh having a carrier concentration lower than that of the drift region Rd is generated as illustrated in FIG. 8. The high-resistance layer Lh contains a defect having a deep level, which leads to increase of deep leakage current and degradation of the efficiency of carrier injection from the back surface. Thus, generation of the high-resistance layer Lh is not preferable. FIG. 9 is a schematic diagram illustrating the relation between an activation time T and the distance Z of the hydrogen buffer layer 13 from the back surface electrode 16 at which generation of the high-resistance layer Lh starts when the oxygen concentration in the semiconductor substrate 1 is 6E17 atoms/cm³ and the activation temperature of hydrogen is fixed to 400° C. As illustrated in FIG. 9, a range in which the high-resistance layer Lh is not generated can be expressed as Z<0.03T+5 in the range of 30<T<240 min where T [min] is the activation time and Z is the distance of the hydrogen buffer layer 13 from the back surface electrode 16. As described above, hydrogen diffusion changes with the oxygen concentration in the semiconductor substrate 1, and when the oxygen concentration in the semiconductor substrate 1 is 1E16 atoms/cm³, the range in which the high-resistance layer Lh is not generated can be expressed as Z<0.16T+21 in the range of 30<T<240 min.

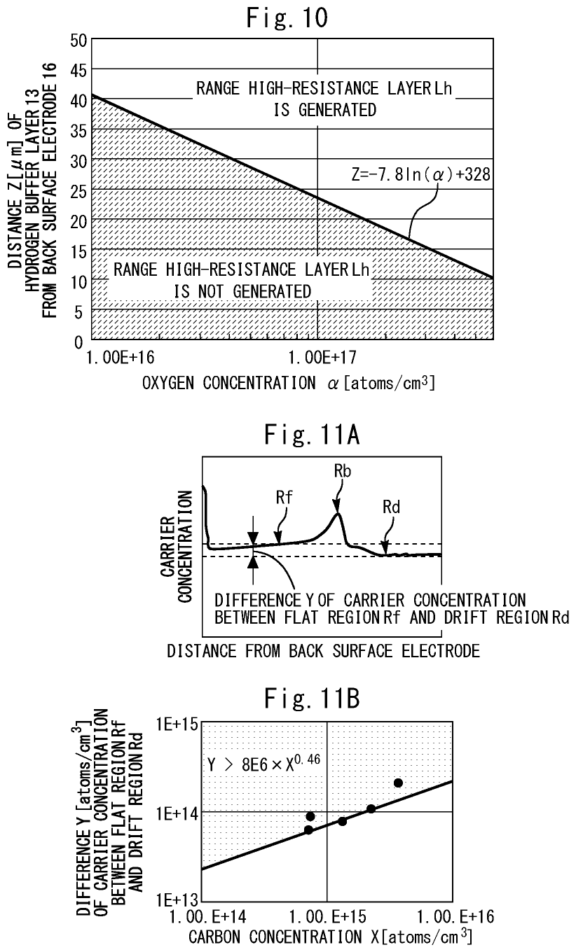

As illustrated in FIG. 10, when hydrogen injection is fixed at a dose amount with which the hydrogen buffer layer 13 has a peak concentration of 1E15 atoms/cm³ or lower and the activation condition of hydrogen is fixed at 400° C. and 120 minutes, the oxygen concentration in the semiconductor substrate 1 and the distance Z of the hydrogen buffer layer 13 from the back surface electrode 16 at which the high-resistance layer Lh is not generated can be expressed as Z<−7.81n(α)+328 in the range of 1E16 atoms/cm³<α<6E17 atoms/cm³ where a [atoms/cm³] is the oxygen concentration.

The carrier concentration of the flat region Rf tends to increase in proportion to increase of the carbon concentration in the semiconductor substrate 1. For example, in the present embodiment, as illustrated in FIG. 11B, the expression of Y>8E6×X^{0.46} is obtained where Y [atoms/cm³] is the difference between the carrier concentration of the flat region Rf and the carrier concentration of the drift region Rd and X [atoms/cm³] is the carbon concentration of the flat region Rf.

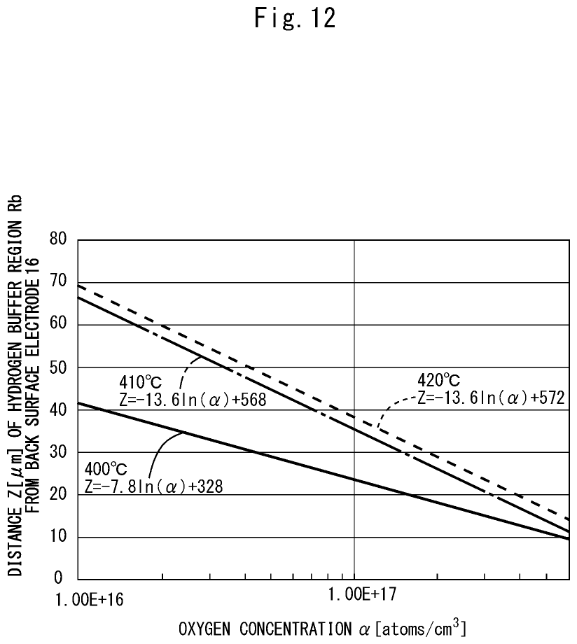

The activation temperature of hydrogen is fixed to 400° C. in the above description, but the activation temperature may be increased as long as there is no influence on the front surface. Increase of the activation temperature assists hydrogen diffusion and makes it possible to increase the distance Z of the hydrogen buffer layer 13 from the back surface electrode 16 at which the high-resistance layer Lh is not generated. For example, FIG. 12 illustrates the relation between the oxygen concentration of the semiconductor substrate 1 and the distance Z of the hydrogen buffer layer 13 from the back surface electrode 16 when the activation temperature is set to be high at 410° C. and 420° C. One of the reasons that the gradients of straight lines for 410° C. and 420° C. are larger than the gradient of a straight line for 400° C. is thought to be because of the temperature zone in which defects generated at a level due to injection start to abruptly recover. Thus, defect loss needs to be considered when the activation temperature of hydrogen is to be increased.

As described above, defects generated due to hydrogen injection is important for hydrogen diffusion and electrical characteristics. Typically, a low crystalline region having various atom arrangements is formed, due to collision between a hydrogen ion and a silicon atom, in a hydrogen passing region through which injected hydrogen has passed. For example, in the semiconductor substrate 1, a carbon atom (Cs) in a stable state is trapped at a lattice point of silicon crystal in place of a silicon atom in the crystal, but the carbon atom is released to an interstitial space by hydrogen injection energy. It has been reported that the interstitial carbon atom (Ci) couples with an interstitial oxygen atom, thereby generating a carrier trap (CiOi). The carrier trap as an electron trap in a region sandwiched between the hydrogen buffer layer 13 and the phosphorus buffer layer 14 causes leakage current increase and formation failure of a back-surface diffusion profile. Thus, it is not preferable that the electron trap remains in the diffusion profile.

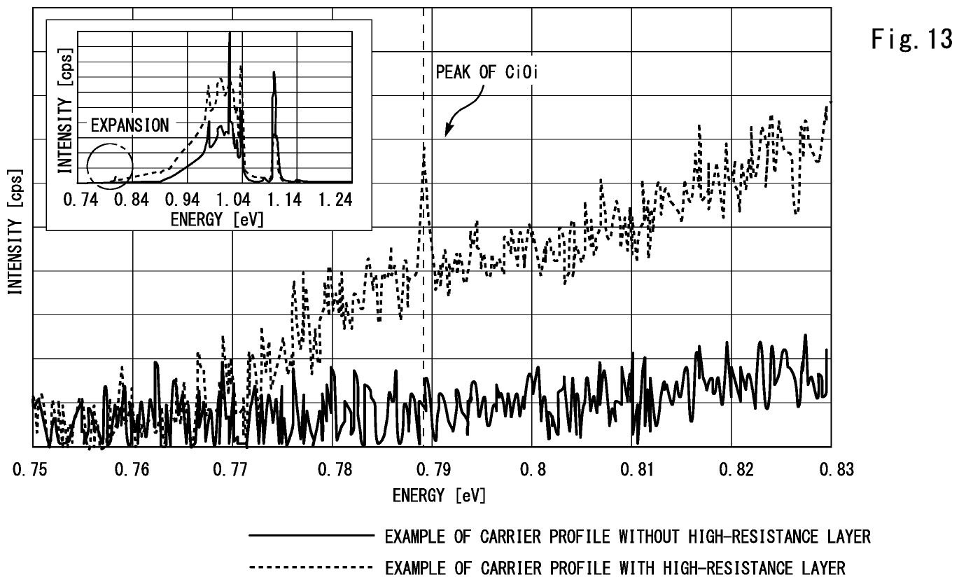

For the semiconductor device obtained in the present embodiment, a peak of the carrier trap (CiOi) is not observed at the energy of 0.79 eV as illustrated with a solid line in a photoluminescence spectrum of the flat region Rf in FIG. 13. Thus, in the semiconductor device according to the present embodiment, no high-resistance layer Lh is generated and no carrier trap (CiOi) exists in the flat region Rf. For reference, a peak of the carrier trap (CiOi) is observed at the energy of 0.79 eV as illustrated with a dashed line when the high-resistance layer Lh is generated.

As described above, according to the present embodiment, the hydrogen buffer layer 13 has an effect of reducing dynamic abrupt change of a depleted layer, for example, during switching, thereby decreasing surge voltage and preventing oscillation. Surge voltage decrease is useful for increase of dynamic withstand voltage, and oscillation prevention is useful for noise reduction. In particular, in the present embodiment, a buffer profile without the high-resistance layer Lh is obtained by appropriately setting the distance Z from the back surface electrode to the hydrogen buffer layer for the oxygen concentration Co of the semiconductor substrate 1. In other words, no anomaly occurs to formation of a carrier concentration profile. Moreover, the carrier concentration of the flat region Rf can be controlled because the carrier concentration of the flat region Rf increases in proportion to the carbon concentration in the semiconductor substrate 1, and leakage current reduction can be achieved because increase of the carrier concentration of the flat region Rf can prevent hole injection from the back surface. The activation condition of hydrogen at 400° C. or lower can minimize heat influence on a front surface structure of the semiconductor device. For example, it is possible to minimize diffusion of the front surface electrode in the semiconductor substrate and characteristics change of a front surface protection material due to heat. To achieve surge voltage decrease and oscillation prevention, the activation temperature may be set to be higher for adjustment to increase the distance Z of the hydrogen buffer layer 13 from the back surface electrode 16. Moreover, since no carrier trap (CiOi) generated due to hydrogen injection exists in the flat region Rf of the semiconductor device, it is possible to decrease leakage current and prevent formation failure of the back-surface diffusion profile.

### REFERENCE SIGNS LIST

1 . . . semiconductor substrate, 14 . . . phosphorus buffer layer (carrier injection layer), layer (carrier injection layer), Rb . . . hydrogen buffer region, Rd . . . drift region, Rf . . . flat region

1. A semiconductor device comprising:
a drift region that is of a first conductive type and positioned in a semiconductor substrate having a front surface and a back surface;
a hydrogen buffer region that is of the first conductive type, positioned on the back surface side of the drift region, contains hydrogen as impurities, and has an impurity concentration higher than an impurity concentration of the drift region;
a flat region that is of the first conductive type, positioned on the back surface side of the hydrogen buffer region, and has an impurity concentration higher than the impurity concentration of the drift region; and
a carrier injection layer that is of the first conductive type or a second conductive type, positioned on the back surface side of the flat region, and has an impurity concentration higher than the impurity concentrations of the hydrogen buffer region and the flat region,
wherein the hydrogen buffer region and the flat region each have a constant oxygen concentration of 1E16 atoms/cm³ to 6E17 atoms/cm³ inclusive.

2. The semiconductor device according to claim 1, wherein a relation of Y>8E6×X^{0.46} is satisfied where Y is a carrier concentration difference between the flat region and the drift region and X is a carbon concentration of the flat region.

3. The semiconductor device according to claim 1, wherein no peak exists at 0.79 eV in a photoluminescence spectrum of the flat region.

4. A method of manufacturing the semiconductor device according to claim 1, the method comprising:
a step of preparing the semiconductor substrate having an oxygen concentration of 1E16 atoms/cm³ to 6E17 atoms/cm³ inclusive;
an injection step of injecting protons within a depth of 10 μm from the back surface of the semiconductor substrate in a dose amount of 4E13 atoms/cm³ or smaller; and
an activation step of activating the protons injected in the injection step through thermal treatment at 400° C.,
wherein a relational expression of Z<0.03T+5 is satisfied in a range of 30<T<240 where Z μm is the depth and Tmin is a thermal treatment time in the activation step.

5. A method of manufacturing the semiconductor device according to claim 1, the method comprising:
a step of preparing the semiconductor substrate having an oxygen concentration of 1E16 atoms/cm³ to 6E17 atoms/cm³ inclusive;
an injection step of injecting protons within a depth of 15 μm from the back surface of the semiconductor substrate in a dose amount of 4E13 atoms/cm³ or smaller; and
an activation step of activating the protons injected in the injection step through thermal treatment at 430° C. for 120 minutes.
